(19) United States
(12) Patent Application Publication
(10) Pub. No.: US 2002/0190791 A1
(43) Pub. Date: Dec. 19, 2002

(54) High frequency amplifier for amplifying high frequency signals

(76) Inventors: Christoph Peter Serbe, Edisonstrasse (CH); Klaus Ruzicka, Mutschellenstrasse (CH)

Correspondence Address: McCormick, Paulding & Huber, City Place II, 185 Asylum Street, Hartford, CT, 06103-3402, US

(21) Appl. No.: 10/165,165

(22) Filed: Jun. 7, 2002

(30) Foreign Application Priority Data
Jun. 15, 2001 (CH) 200110099/01

(51) Int. Cl. H03F 3/68

(52) U.S. Cl. 330/124 R

(57) ABSTRACT

Amplifier circuit (10) for amplifying a high frequency input signal (RF In) which is applied to the input (11) and is supplied from there to a power divider (12). The power divider (12) is linked to the input (11) in such a way that the high frequency input signal (RF In) is divided into two partial signals RF1 and RF2 having equal power. The two partial signals RF1 and RF2 are provided at the two outputs (13) and (14) of the power divider (12). The power divider (12) is followed by a low-resistance parallel circuit made of a first amplifier block (15), which is connected to the output (13) of the power divider (12), and a second amplifier block (16), which is connected to the second output (14) of the power divider (12). The main transistor (21) of the amplifier circuit (10) has an input (22) which is linked to the joint output (20) of the low-resistance parallel circuit (17). The transistor (21) amplifies the signal (RF4) applied to the input of the transistor (21) and provides a high frequency output signal (RF3) at the output (23), which is amplified in relation to the high frequency input signal (RF In). In this case, the entire arrangement is preferably not operated in saturation.

### CROSS REFERENCE TO RELATED APPLICATION

This application claims priority from and incorporates by reference the subject matter of Swiss Patent Application No. 2001 1099/01 filed on Jun. 15, 2001.

### BACKGROUND INFORMATION

The present invention relates to an amplifier for amplifying high frequency signals and a use of this amplifier. These types of amplifiers are particularly suitable for use in electrooptical modulators.

There are various types of amplifier circuits, which are, however, only conditionally suitable for use in the high frequency range. Amplifier circuits which are suitable for the amplification of low frequency signals may not simply be used in the high frequency range, since this range has its own laws which apply.

High frequency amplifiers according to the related art are typically operated in saturation. In other words, the transistors of these high frequency amplifiers are driven in such a way that they operate in the saturation range above the saturation voltage of the transistors. In this case, the transistors are normally driven in a way tailored to this, for example using 50 ohm driving.

The object of the present invention is therefore,

to provide an amplifier having higher bandwidth,

to provide an amplifier having a higher power output,

to provide an amplifier having smoother transfer function

to provide an amplifier which fulfills the above requirements without being operated in saturation, and

to suggest a use of this type of amplifier.

This object is achieved according to the present invention

for the amplifier by the features comprising a power divider that splits a high frequency input signal into two parts and separate amplifier blocks for each part. The outputs of the amplifier blocks are then combined as an input to a main transistor of the amplifier.

The high frequency amplifier may be used in a communication system with an electrooptical modulator to amplify a modulating signal controlling the modulator.

Advantageous refinements of the amplifier are also disclosed.

According to the present invention, the amplifier circuit is constructed around a transistor (main transistor).

It is an advantage of the amplifier circuit according to the present invention that it is rapid, generates a high power output, and has good transfer properties (i.e., e.g. a relatively smooth transfer function and a high bandwidth). The main transistor is not operated in saturation in this case.

In an advantageous embodiment, the amplifier circuit has an output impedance of approximately 50 ohm.

The amplifier circuit according to the present invention is universally usable. It may, for example, be used in microwave applications and other high frequency signal processing systems.

### BRIEF DESCRIPTION OF THE DRAWINGS

Further properties and advantages of the present invention are described in detail in the following with reference to the description and in relation to the drawing.

FIG. 1 shows a first amplifier circuit according to the present invention;

FIG. 2 shows a second amplifier circuit according to the present invention;

FIG. 3 shows a supply network according to the present invention;

FIG. 4 shows a feedback network according to the present invention;

FIG. 5 shows a power divider according to the present invention;

FIG. 6 shows a communication system, having an electrooptical modulator, according to the present invention.

### DETAILED DESCRIPTION OF THE PREFERRED EMBODIMENTS

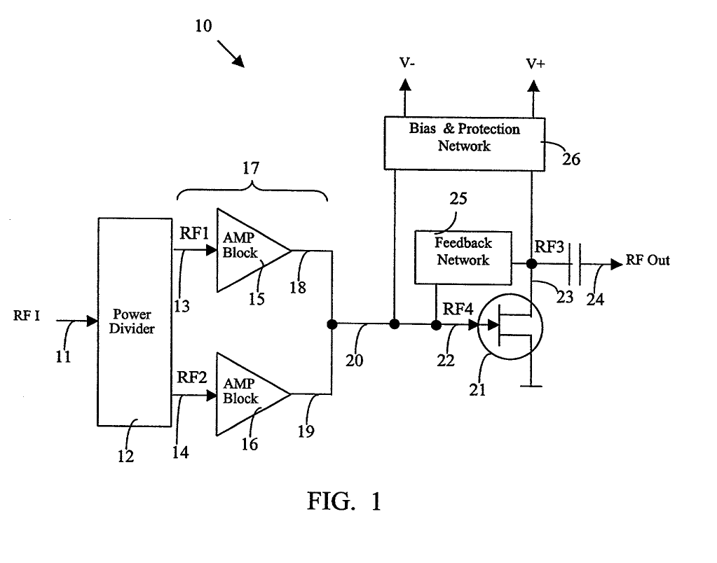

The operating principle of the present invention is described in connection with a first exemplary embodiment. This first exemplary embodiment is illustrated in FIG. 1 in the form of a schematic block diagram.

Amplifier circuit 10 shown in FIG. 1 is suitable for amplifying a high frequency input signal RF In. Input signal RF In is applied to an input 11 and is fed from there to a power divider 12. Power divider 12 is linked to input 11 in such a way that high frequency input signal RF In is divided into two partial signals RF1 and RF2 having equal power. Both partial signals RF1 and RF2 are provided at both outputs 13 and 14 of power divider 12. Power divider 12 is followed by a low-resistance parallel circuit 17 made of a first amplifier block 15, which is connected to output 13 of power divider 12, and a second amplifier block 16, which is connected to second output 14 of power divider 12.

Output 18 of first amplifier block 15 and output 19 of second amplifier block 16 are led to a joint output 20 of low-resistance parallel circuit 17. Main transistor 21 of amplifier circuit 10 has an input 22 (gate) which is linked to joint output 20 of low-resistance parallel circuit 17. Transistor 21 amplifies signal RF4 applied to the input of transistor 21 and provides a high frequency output signal RF3 at output 23 (drain), which is amplified in relation to high frequency input signal RF In.

In the example shown, main transistor 21 is an n-channel barrier layer field effect transistor (FET). FET transistors for medium power, for example, are particularly suitable, preferably for outputs between 250 mW and 3 W. Transistors which are suitable for use in connection with the present invention typically have a gate width between 0.5 and 5 mm. Examples of particularly suitable transistors are: Agilent AFT 44101, Agilent AFT 45101, Agilent AFT 46101, or comparable types.

In addition to the elements mentioned, amplifier circuit 10 may have a feedback network 25, which connects output 23 of transistor 21 to its input 22. Details of a possible feedback network 25 are shown in FIG. 4. Feedback network 25 shown may, for example, include a series circuit made of a coil L2, a resistor R2, and a capacitor C2.

Furthermore, the operating point of transistor 21 may be preset via bias network 26 (supply network). Bias network 26 may also, as shown in FIG. 1, include a protective network. A protective network of this type preferably has two opposite parallel diodes, which are linked to output 23 of the transistor 21 in order to reduce signal peaks which are applied to output 24 of amplifier circuit 10. This protective circuit is preferably connected directly to output 23 of transistor 21.

Bias network 26 is preferably to be laid out in such a way that transistor 21 is operated in the linear region of the transfer characteristic during normal operation.

In a further embodiment of the present invention, amplifier circuit 10 is wired in such a way that it has an impedance of 50 ohm. In other words, output 24 of the amplifier circuit 10 has a matching impedance of approximately 50 ohm.

In an advantageous embodiment, both amplifier blocks 15 and 16 are dimensioned in such a way that low-resistance parallel circuit 17 has an impedance of less than 30 ohm, preferably less than 20 ohm. The impedance for driving the main transistor is reduced by the parallel circuit of two amplifier blocks.

The amplifier circuit may be designed so that output 24 of amplifier circuit 10 operates on an inductance.

For use in communication systems, it is advantageous if amplifier circuit 10 is dimensioned in such a way that it has a high bandwidth. This may be achieved if, for example, a feedback network 25 is used. In this way, reduced amplification, but a higher bandwidth are achieved. A parallel circuit of a resistor and a capacitor may also be positioned in the signal path in order to improve the bandwidth.

In a preferred embodiment of the invention, first amplifier block 15 and second amplifier block 16 are laid out symmetrically. In addition, first amplifier block 15 and second amplifier block 16 may be implemented in such a way that they suppress reflections which run from input 22 of transistor 21 back in the direction of both amplifier blocks 15 and 16. This may be achieved, for example, by suppressing standing waves between input 11 and input 22 of transistor 21. This ripple factor would have negative effects on the response characteristic of amplifier circuit 10.

If, for example, amplifier blocks 15 and 16 are used, which each have an amplification factor A in the forward direction of A>2, and preferably A>10, then a damping of 1/A results in the backward direction, which is sufficient to suppress reflections. Therefore, one no longer observes, at input 11, anything of the actual mismatch (input impedance smaller than 50 ohm) at input 22 of the transistor 21.

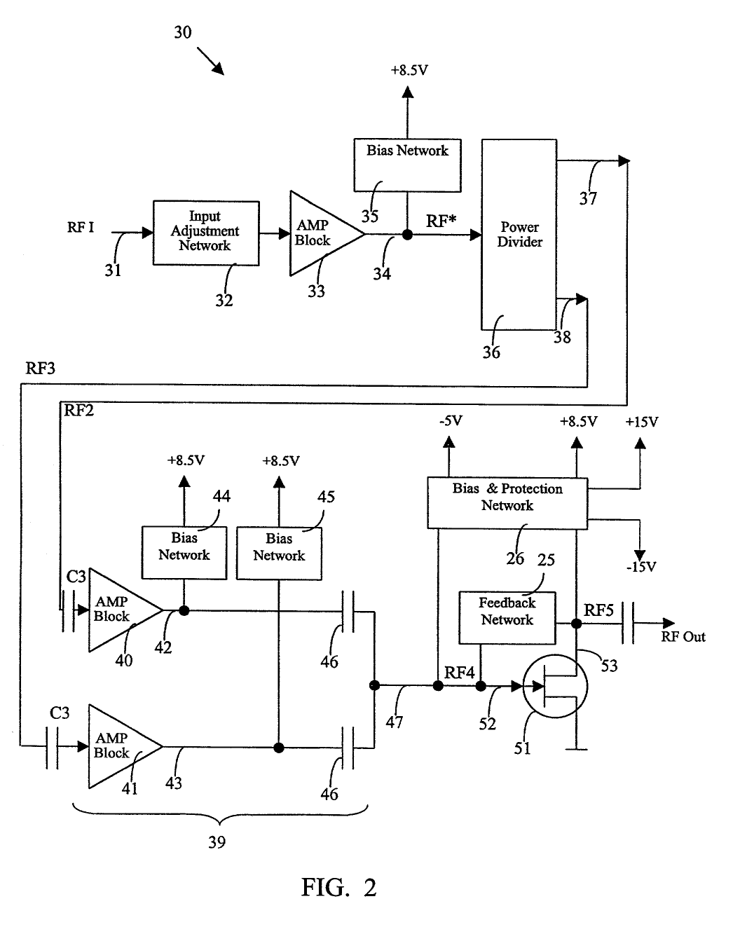

A further embodiment of the invention is shown in FIG. 2. Amplifier circuit 30 shown has a very similar construction to circuit 10 shown in FIG. 1. Circuit 30 has the following components and elements. At input 31 RF In, an adjustment network 32 is located, followed by an input amplifier 33. Output 34 of input amplifier 33 is set to a suitable operating point (e.g. Va) by bias network 35 and then fed to the input of a power divider 36.

Power divider 36 is linked to output 34 of input amplifier 33 in such a way that high frequency input signal RF* is divided into two partial signals RF2 and RF3 of equal power. The two partial signals RF2 and RF3 are provided at the two outputs 37 and 38 of power divider 36. Power divider 36 is followed by a low-resistance parallel circuit 39 made of a first amplifier block 40, which is connected to output 37 of power divider 36, and a second amplifier block 41, which is connected to second output 38 of power divider 36. Both outputs 42 and 43 of the amplifier blocks 40 and 41 are each set to a suitable operating point by bias network 44 and/or 45 and are then brought together to a joint output 47 of low-resistance parallel circuit 39 via two capacitors 46.

Circuit 30 has a main transistor 51, whose input 52 (gate) is linked to joint output 47 of low-resistance parallel circuit 39. In embodiment 30 shown, joint output 47 is linked directly to input 52 (gate) of transistor 51.

In a further embodiment, this linkage may be produced via an RC element, which is positioned between joint output 47 and input 52 (gate) of transistor 51. This RC element may be dimensioned in such a way that the frequency response may be corrected. For this purpose, the RC element may, for example, comprise a resistor having a capacitor connected in parallel.

Transistor 51 amplifies signal RF4 applied to input 52 of transistor 51 and provides a high frequency output signal RF5 at output 53 (drain), which is amplified in relation to high frequency input signal RF In.

In addition to the elements mentioned, amplifier circuit 30 may have a feedback network 25 which connects output 53 of transistor 51 to its input 52.

Furthermore, the operating point of transistor 51 may be preset via bias network 26. Bias network 26 may, for example, include a protective network in order to reduce the signal peaks applied at output 54 of amplifier circuit 30.

Bias network 26 is preferably to be laid out in such a way that transistor 51 is, during normal operation, operated in the linear range of the transfer characteristic.

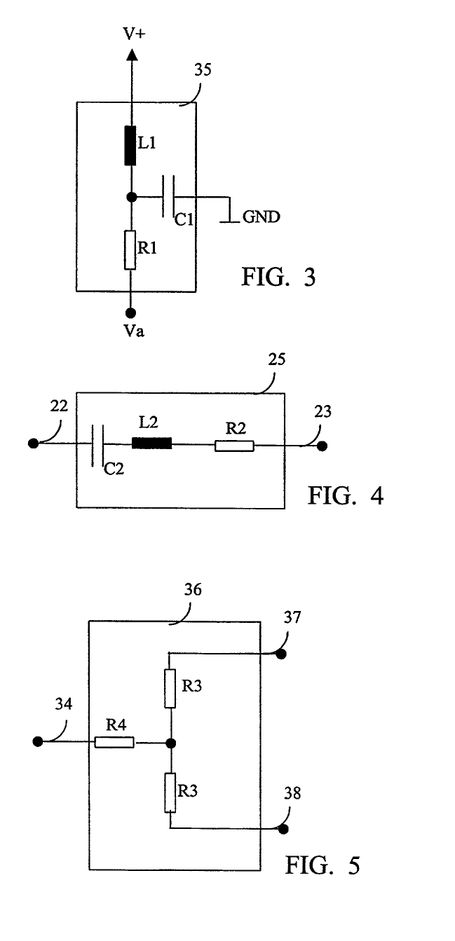

The bias network (for example bias network 35 in FIG. 2) may include a supply network which comprises a combination of conventional components (e.g. coils, capacitors, and resistors). Such a supply network is typically supplied by a supply voltage V+(e.g. between 5 V and 20 V) as shown in FIG. 3. Output voltage Va of the supply network is between the supply voltage V+and 0 V.

The power divider is preferably a resistor power divider which is matched in all three directions (i.e. in relation to the input and the two outputs). Such a power divider 36 may, for example, be constructed from a network having multiple resistors R3 and R4, as shown in FIG. 5. Optionally, capacitors C3 may be used as decoupling capacitors for the amplifier blocks.

The amplifier circuit according to the present invention may be modified by providing a low-resistance parallel circuit of more than two amplifier blocks, which drive the main transistor.

The low-resistance driving of the main transistor is, for practical purposes, intentionally incorrect driving.

The amplifier circuit according to the present invention may be used as, among other things, a component of a transmission system, particularly in a transmission system having fiber-optic transmission paths.

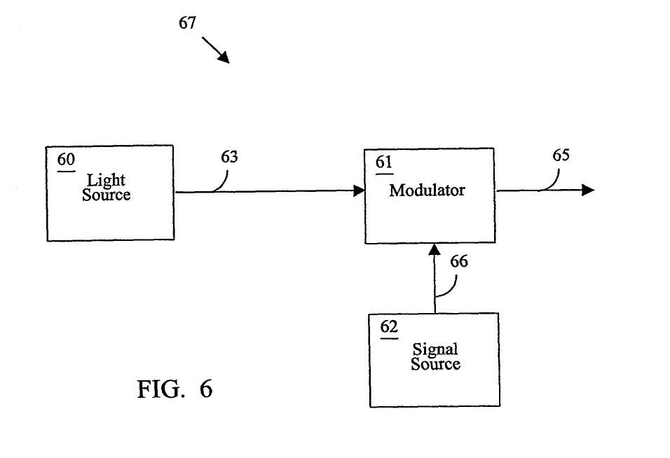

The amplifier circuit may advantageously be used to drive an electrooptical modulator which emits modulated light. The light is modulated by an electrical signal which the amplifier circuit provides at the output. An example of a corresponding arrangement is shown in FIG. 6. Electrooptical modulator 61 may be a component of a communication system 67 (e.g. an amplifier) which, besides electrooptical modulator 61, has a light source 60 and a signal source 62. Light source 60, e.g. a continuous wave (CW) laser, generates a light wave which is fed into electrooptical modulator 61 via a fiber 63. Signal source 62 provides a high frequency signal which, using an amplifier circuit 10 or 30 according to the present invention, is amplified and supplied to electrooptical modulator 61 via a line 66. Electrooptical modulator 61 modulates the light wave using the amplified high frequency signal in order to provide a modulated light wave at an output 65. The modulated light wave may, for example, be fed into a fiber-optic transmission path or be used for optical free space communication, for example between satellites or between a satellite and a ground station.

What is claimed is:

1. An amplifier circuit (10, 30) for amplifying a high frequency input signal (RF In), having
an input (11; 31) for the high frequency input signal (RF In),
a power divider (12; 36) which is linked to the input (11; 31) in such a way that it divides the high frequency input signal (RF In) into two partial signals having equal power and provides them at two outputs (13, 14; 37, 38) of the power divider (12; 36),
a first amplifier block (15; 40) which is connected to a first of the two outputs (13; 37) of the power divider (12; 36),
a second amplifier block (16; 41), which is connected to the second of the two outputs (14; 38) of the power divider (12; 36), with the first amplifier block (15; 40) and the second amplifier block (16; 41) being positioned in a low-resistance parallel circuit (17; 39) and the output (18; 42) of the first amplifier block (15; 40) being joined together with the output (19; 43) of the second amplifier block (16; 41) into a joint output (20; 47),
a transistor (21; 51), whose input (22; 52) is linked to the joint output (20; 47) and is drivable by the low-resistance parallel circuit (17; 39) and, at an output (23; 53), provides a high frequency output signal (RF3), which is amplified in relation to the high frequency input signal (RF In).

2. The amplifier circuit (10; 30) according to claim 1, wherein the output (23; 53) of the transistor (21; 51) is wired in such a way that the amplifier circuit (10; 30) has an output impedance of 50 ohm.

3. The amplifier circuit (10; 30) according to claim 1, wherein the low-resistance parallel circuit (17) has an impedance of less than 30 ohm, preferably less than 20 ohm.

4. The amplifier circuit (10; 30) according to claim 1, wherein the output (23; 53) of the transistor (21; 51) is wired in such a way that the amplifier circuit (10; 30) operates on an inductance.

5. The amplifier circuit (10; 30) according to claim 1, wherein the transistor (21; 51) is wired in such a way that it is operated in the linear range.

6. The amplifier circuit (10; 30) according to, claim 1 wherein the amplifier circuit (10; 30) is dimensioned in such a way that the output (24; 54) of the amplifier circuit (10; 30) has a matching impedance of approximately 50 ohm.

7. The amplifier circuit (10; 30) according to claim 1, wherein the amplifier circuit (10; 30) is dimensioned in such a way that it has a high bandwidth.

8. The amplifier circuit (10; 30) according to claim 1, wherein the first amplifier block (15; 40) and the second amplifier block (16; 41) are laid out symmetrically.

9. The amplifier circuit (10; 30) according to claim 1, wherein the first amplifier block (15; 40) and the second amplifier block (16; 41) are laid out in such a way that they suppress reflections, which run from the input (22; 52) of the transistor (21; 51) back in the direction of the first amplifier block (15; 40) and the second amplifier block (16; 41).

10. The amplifier circuit (10; 30) according to claim 1, wherein the first amplifier block (15; 40) and the second amplifier block (16; 41) are laid out in such a way that standing waves between the input (11; 31) for the high frequency input signal (RF In) and the input (22; 52) of the transistor (21; 51) are suppressed.

11. The amplifier circuit (10; 30) according to claim 1, wherein a protective network, is linked to the output (23; 53) of the transistor (21; 51) in order to reduce signal peaks applied to the output (24; 54) of amplifier circuit (10; 30).

12. The amplifier circuit (10; 30) according to claim 1, wherein the amplifier circuit (10; 30) is dimensioned as a driver for an electrooptical modulator.

13. The amplifier circuit (10; 30) according to claim 1, wherein the amplifier circuit (10; 30) is dimensioned in such a way that it is suitable for amplification of a microwave input signal (RF In).

14. A use of an amplifier circuit (10; 30) according to claim 1 in a communication system (67), which has a light source (60), an electrooptical modulator (61), and a signal source (62), wherein
the light source (60) feeds a light wave into the electrooptical modulator (61) via a fiber (63),
the signal source (62) amplifies a high frequency signal using the amplifier circuit (10; 30) and supplies it to the electrooptical modulator (61) via a line (66),
the electrooptical modulator (61) modulates the light wave using the amplified high frequency signal and provides a light wave at an output (65).

15. (New) A communication system comprising:
a light source producing a light wave,
an electrooptical modulator connected with the light source to receive a light wave signal from the light source and modulate the signal; and
a signal source providing a high frequency signal controlling the modulation of the light wave signal; the signal source producing the high frequency signal from a signal amplifier
the high frequency signal amplifier having a power divider splitting a high frequency input signal into two parts;
two amplifier blocks, one amplifier block receiving and amplifying one part of the split input signal, and the other amplifier block receiving and amplifying the other part of the split input signal;
the output of the two amplifier blocks being joined together to combine the amplified signals; and
a transistor receiving the combined amplified signals to produce a high frequency output signal which is amplified in relation to the high frequency input signal.
